(19) United States
(12) Patent Application Publication
(10) Pub. No.: US 2026/0363010 A1
(43) Pub. Date: Nov. 12, 2026

(54) LIQUID STORAGE APPARATUS AND SYSTEM FOR SUPPLYING LIQUID

(71) Applicant: Samsung Electronics Co., Ltd., Suwon-si (KR)

(72) Inventors: Taebok Kim, Suwon-si (KR); Changhun Lee, Suwon-si (KR)

(21) Appl. No.: 19/384,521

(22) Filed: Nov. 10, 2025

(30) Foreign Application Priority Data
May 8, 2025 (KR) 10-2025-0059889

(51) Int. Cl. H10P 72/00; B65D 88/54

(52) U.S. Cl. CPC H10P 72/0402; B65D 88/54

(57) ABSTRACT

A liquid storage apparatus includes a tank body including an accommodation space configured to store a processing liquid and an inlet pipe on the tank body and in the accommodation space to flow the processing liquid into the accommodation space. The inlet pipe includes a flow path configured such that the processing liquid flows through the flow path; a first discharge port at a lower end of the inlet pipe and in communication with the flow path and the accommodation space; and a second discharge port at a sidewall of the inlet pipe. In the height direction of the tank body, a portion of the second discharge port is located at a level that is higher than a level of the first discharge port. The second discharge port is in communication with the flow path and the accommodation space.

### CROSS-REFERENCE TO RELATED APPLICATIONS

This application claims benefit of priority to Korean Patent Application No. 10-2025-0059889 filed on May 8, 2025 in the Korean Intellectual Property Office, the disclosure of which is incorporated herein by reference in its entirety.

### BACKGROUND

Aspects of the present inventive concept relate to a liquid storage apparatus and a liquid supply system, capable of efficiently removing bubbles from a processing liquid.

Generally, in order to manufacture a semiconductor device, a plurality of processes such as a deposition process, a photo process, an etching process, a cleaning process, or the like may be required, and a plurality of devices may be used. For example, in a photo process or the like, a liquid supply system may be used to supply various types of processing liquids to a substrate in a substrate treatment facility such as a spinner coater facility or the like, thereby performing a photo treatment process. The liquid supply system may be equipped with various components for supplying liquids to the substrate. When a processing liquid is discharged onto the substrate in a state in which a remaining amount of the processing liquid is insufficient, using this liquid supply system, a coating defect may occur due to the processing liquid and air being mixed and discharged. In order to prevent such a coating defect on the substrate, the liquid supply system may be equipped with a buffer tank used as an intermediate storage tank for the processing liquid.

However, in a commonly used buffer tank, since a processing liquid may flow into a lower end portion of the buffer tank, when the processing liquid has a high degree of viscosity, the highly viscous processing liquid does not easily rise by its own buoyancy, and thus bubbles may still be mixed into the substrate when the processing liquid is discharged from the buffer tank, resulting in poor coating.

### SUMMARY

Some examples of the present inventive concept provide a liquid storage apparatus capable of efficiently removing bubbles from a processing liquid.

Some examples of the present inventive concept provide a liquid supply system capable of efficiently removing bubbles from a processing liquid in a liquid storage apparatus and preventing occurrence of poor processing due to bubbles being mixed into a substrate.

A liquid storage apparatus according to example embodiments includes a tank body including an accommodation space configured to store a processing liquid; an inlet pipe disposed on the tank body and in the accommodation space to flow the processing liquid into the accommodation space, the inlet pipe extending in a height direction of the tank body; and an outlet pipe disposed on the tank body, the outlet pipe being configured such that the processing liquid flows out from the accommodation space through the outlet pipe, wherein the inlet pipe includes: a flow path configured such that the processing liquid flows through the flow path; a first discharge port provided at a lower end of the inlet pipe and in communication with the flow path and the accommodation space; and a second discharge port provided at a sidewall of the inlet pipe, wherein, in the height direction of the tank body, at least a portion of the second discharge port is located at a level that is higher than a level of the first discharge port, and wherein the second discharge port is in communication with the flow path and the accommodation space.

A liquid storage apparatus according to example embodiments includes a tank body including an accommodation space configured to store a processing liquid; an inlet pipe disposed on the tank body and in the accommodation space to flow the processing liquid into the accommodation space, the inlet pipe extending in a height direction of the tank body; an outlet pipe disposed on the tank body, the outlet pipe being configured such that the processing liquid flows out from the accommodation space through the outlet pipe; and a first level sensor disposed on the tank body and configured to sense a first set level of the processing liquid in the accommodation space at which filling of the processing liquid in the accommodation space is configured to begin, wherein the inlet pipe includes: a flow path configured such that the processing liquid flows through the flow path; a first discharge port provided at a lower end of the inlet pipe and in communication with the flow path and the accommodation space; and a second discharge port having a slit shape extending in an extension direction of the inlet pipe, the second discharge port opening toward a radial center of the accommodation space, and the second discharge port being in communication with the flow path and the accommodation space, and wherein, in the height direction of the tank body, a first end of the second discharge port is at a level higher than a level of the first discharge port, and a second end of the second discharge port opposite to the first end is adjacent to the first discharge port.

A liquid supply system according to example embodiments includes a liquid supply line of which one end is connected to a liquid supply source configured to supply a processing liquid; a liquid storage apparatus disposed on the liquid supply line and configured to temporarily store therein the processing liquid supplied from the liquid supply source; a pressurized gas supply line connected to the liquid storage apparatus; a drain line connected to the liquid storage apparatus; a pump disposed on the liquid supply line and configured to pump the processing liquid; and a discharge nozzle disposed at the other end of the liquid supply line and configured to discharge the processing liquid supplied from the liquid storage apparatus to a substrate treatment device, wherein the liquid storage apparatus includes: a tank body including an accommodation space configured to store the processing liquid; an inlet pipe disposed on the tank body and in the accommodation space to flow the processing liquid into the accommodation space, the inlet pipe extending in a height direction of the tank body; an outlet pipe disposed on the tank body, the outlet pipe being configured such that the processing liquid flows out from the accommodation space through the outlet pipe; a gas supply disposed on the tank body, connected to the pressurized gas supply line, and configured to supply a pressurized gas to the accommodation space; and a discharge line disposed on the tank body and connected to the drain line, and wherein the inlet pipe includes: a flow path configured such that the processing liquid flows through the flow path; a first discharge port provided at a lower end of the inlet pipe and in communication with the flow path and the accommodation space; and a second discharge port provided at a sidewall of the inlet pipe, wherein at least a portion of the second discharge port is located at a level in the height direction that is higher than a level of the first discharge port, and wherein the second discharge port is in communication with the flow path and the accommodation space.

### BRIEF DESCRIPTION OF DRAWINGS

These and other aspects, features, and advantages of the present inventive concept will be more clearly understood from the following detailed description, taken in conjunction with the accompanying drawings, in which:

FIG. 1 is a view illustrating a liquid supply system according to example embodiments.

FIG. 2 is a perspective view illustrating a liquid storage apparatus according to example embodiments.

FIG. 3 is a view illustrating a liquid storage apparatus according to example embodiments.

FIG. 4 is a view illustrating an inlet portion having a different shape in a liquid storage apparatus according to example embodiments.

FIG. 5 is a view illustrating a liquid storage apparatus according to example embodiments.

FIG. 6 is a view illustrating a liquid storage apparatus according to example embodiments.

FIG. 7 is a view illustrating a liquid storage apparatus according to example embodiments.

### DETAILED DESCRIPTION

Hereinafter, preferred embodiments will be described with reference to the attached drawings.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

An item, layer, or portion of an item or layer described as “extending” or as extending “lengthwise” in a particular direction has a length in the particular direction and a width perpendicular to that direction, where the length is greater than the width.

Unless otherwise provided, an opening or port formed in a material, that is described as being “adjacent to” or “close to” another opening or port may be as close as possible to the other opening or port within engineering tolerances, without compromising the structural integrity of the material that is present between the ports. Similarly, unless otherwise provided, a first element that is described as being “adjacent to” or “close to” a second element may be as close as possible to the second element within engineering tolerances, so as to avoid any undesirable contact with the second element. An opening or port that is “adjacent to” or “close to” another opening or port may be positioned, for example, within 5 mm of the other opening or port. A first element that is “adjacent to” or “close to” a second element may be positioned, for example, within 5 mm of the second element.

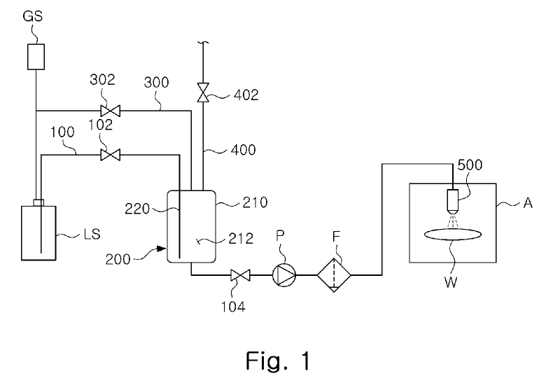

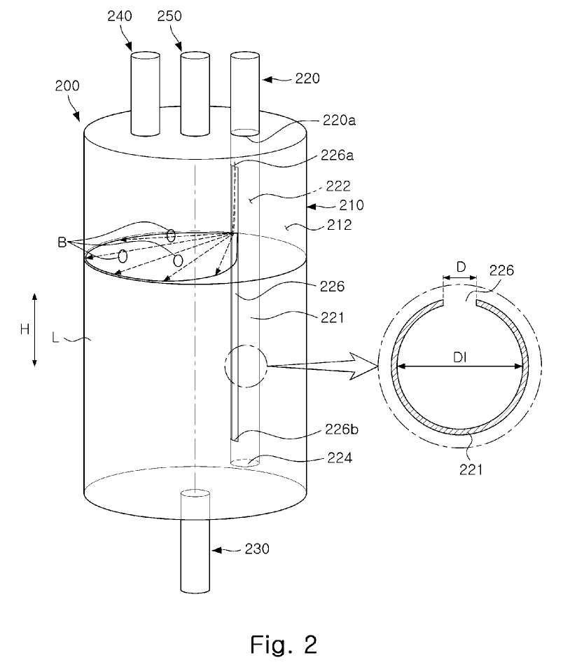

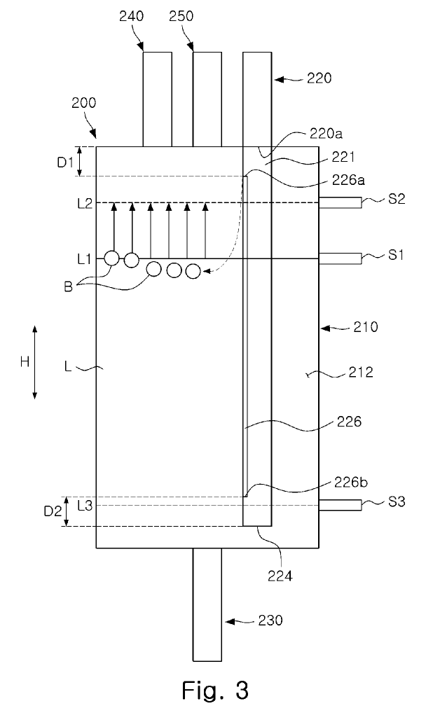

FIG. 1 is a view illustrating a liquid supply system according to example embodiments, FIG. 2 is a perspective view illustrating a liquid storage apparatus according to example embodiments, and FIG. 3 is a view illustrating a liquid storage apparatus according to example embodiments.

Referring to FIGS. 1-3, a liquid supply system according to example embodiments may supply various types of processing liquids to a substrate to perform various processes. In the example embodiments, the liquid supply system may supply a processing liquid such as a photoresist liquid or the like, to the substrate to perform a photo coating process, but is not limited thereto, and may be a liquid supply system used in various processes that may utilize a liquid storage apparatus to be described hereinafter. In the example embodiments, the processing liquid may be a processing liquid having a high viscosity such as a high viscosity resist liquid or the like, but is not limited thereto, and may be a processing liquid having a low viscosity or a medium viscosity.

A liquid supply system according to the example embodiments may include a liquid supply line 100, a liquid storage apparatus 200, a pressurized gas supply line 300, a drain line 400, a pump P, and a discharge nozzle 500.

The liquid supply line 100 may discharge a processing liquid L supplied from a liquid supply source LS through the discharge nozzle 500 to a substrate W in a substrate treatment device A, to perform a process treatment on the substrate W. In the example embodiments, the liquid supply line 100 may have one end connected to the liquid supply source LS supplying the processing liquid L, and the other end connected to the discharge nozzle 500. The liquid supply source LS may be, for example, a supply bottle, but is not limited thereto. The substrate treatment device A may be a device used in various processes for processing the substrate using the processing liquid L. In the example embodiments, the substrate treatment device A may be, but is not limited to, a spin coater supplying the processing liquid L, such as a photoresist liquid or the like, to the substrate W to perform a photo coating process. The liquid supply line 100 may include a valve 102 disposed between the liquid supply source LS and the liquid storage apparatus 200. The valve 102 may open and close a flow path of the processing liquid L flowing through the liquid supply line 100,. The liquid supply line 100 may further include a valve 104 disposed between the liquid storage apparatus 200 and the discharge nozzle 500. The valve 104 may open and close the flow path of the processing liquid L flowing through the liquid supply line 100.

In example embodiments, various components such as a filter F filtering foreign substances in the processing liquid L, a flow meter, a heater, or the like may be disposed in the liquid supply line 100 as needed, but the present inventive concept is not limited thereto, and other components may be disposed in addition thereto.

The liquid storage apparatus 200 may be disposed in the liquid supply line 100 and the processing liquid L supplied from the liquid supply source LS may be temporarily stored therein. In example embodiments, the liquid storage apparatus 200 may be a buffer tank, which may be an intermediate storage tank temporarily storing the processing liquid L, but is not limited thereto. A specific description of the liquid storage apparatus 200 will be described later.

The pressurized gas supply line 300 may be connected to a pressurized gas supply source GS and the liquid storage apparatus 200, and may supply an inert gas, which may be a pressurized gas, from the pressurized gas supply source GS into the liquid storage apparatus 200 to pressurize an internal space of the liquid storage apparatus 200. The inert gas may be, but is not limited to, N2 gas or the like. The liquid storage apparatus 200 may include a gas supply portion 240 (see, e.g., FIGS. 2 and 3) connected to the pressurized gas supply line 300. The gas supply portion 240 (e.g., gas supply or gas supply pipe) may be disposed on a tank body 210 of the liquid storage apparatus 200 to be described hereinafter, and may be connected to the pressurized gas supply line 300 to supply the pressurized gas to an accommodation space 212 of the tank body 210. A supply valve 302 (see, e.g., FIG. 1) for opening/closing a flow path through which the inert gas flows may be disposed on the pressurized gas supply line 300.

The drain line 400 may be connected to the liquid storage apparatus 200. The liquid storage apparatus 200 may include a discharge portion 250 (e.g., a discharge line or a discharge pipe) connected to the drain line 400. The discharge portion 250 may be disposed on the tank body 210 to be described hereinafter. The drain line 400 may be provided with a discharge valve 402 opening/closing a flow path in the drain line 400. The discharge valve 402 of the drain line 400 may operate simultaneously with the valve 102 of the liquid supply line, when the processing liquid L is supplied to the liquid storage apparatus 200, to create a pressure movement path, and when necessary, equipment may be manually operated to discharge the processing liquid L, gas, or the like in the liquid storage apparatus 200 to an outside through the drain line 400.

When supplying the processing liquid L into the liquid storage apparatus 200, the valve 102 of the liquid supply line 100 and the discharge valve 402 of the drain line 400 may be valves operating simultaneously, and may be normally closed, but may operate simultaneously to supply the processing liquid L to the liquid storage apparatus 200, when a signal related to an operation of supplying the processing liquid L into the liquid storage apparatus 200 is accommodated. In addition, when discharging the processing liquid L from the liquid storage apparatus 200 to the discharge nozzle 500 to be described hereinafter, the valve 102 of the liquid supply line 100 and the discharge valve 402 of the drain line 400 may be closed, the supply valve 302 of the pressurized gas supply line 300 and the valve 104 of the liquid supply line 100 may be opened simultaneously, and the processing liquid L discharged from the liquid storage apparatus 200 may be discharged to the substrate through the discharge nozzle 500. When the discharge nozzle 500 includes a pump, the pump of the discharge nozzle 500 may operate simultaneously with an operation of the supply valve 302 of the pressurized gas supply line 300 and the valve 104 of the liquid supply line 100.

The discharge nozzle 500 may be disposed at the other end of the liquid supply line 100, and may discharge the processing liquid L supplied from the liquid storage apparatus 200 to the substrate treatment device A.

In the liquid supply system, in a process of flowing the processing liquid L supplied from the liquid supply source LS into the liquid storage apparatus 200, a microbubble B may be generated. When the processing liquid L containing such a microbubble B is discharged from the liquid storage apparatus 200 to the substrate W through the discharge nozzle 500, the microbubble B may be incorporated into the substrate W, resulting in poor treatment. To efficiently remove the microbubble B included in the processing liquid L in the liquid storage apparatus 200, the liquid storage apparatus 200, as described hereinafter, may be provided in the present inventive concept.

In example embodiments, the liquid storage apparatus 200 may include a tank body 210, an inlet pipe 220, and an outlet portion 230 (e.g., an outlet pipe).

The tank body 210 may include an accommodation space 212 for storing the processing liquid L.

The inlet pipe 220 may be disposed on the tank body 210 such that the processing liquid L flows into the accommodation space 212 of the tank body 210.

The inlet pipe 220 may be disposed to extend in a height direction H of the tank body 210 in the accommodation space 212 of the tank body 210. A portion of the inlet pipe 220 may extend out of and above the tank body 210 to be exposed from an upper portion of the tank body 210, and a different portion of the inlet pipe 220 may be disposed in the accommodation space 212 of the tank body 210.

The outlet portion 230 may be disposed on the tank body 210 (e.g., on an outside or exterior surface of the tank body 210), and may be configured such that the processing liquid L flows out from the accommodation space 212 of the tank body 210 through the outlet portion 230. The outlet portion 230 may be disposed on a bottom portion the tank body 210, and may be connected to a lower surface of the accommodation space 212.

However, arrangement of the outlet portion 230 is not limited thereto, and the outlet portion 230 may be disposed on a lower portion of a sidewall of the tank body 210.

The inlet pipe 220 may be implemented as embodiments having various structures. In example embodiments, the inlet pipe 220 may include a flow path 222 through which the processing liquid L flows, a first discharge port 224, and a second discharge port 226. The flow path 222 may be formed to extend in the height direction H in the inlet pipe 220.

The first discharge port 224 may be provided at (e.g., opened at) a lower end of the inlet pipe 220, and may communicate with (e.g., may be in communication with or in fluid communication with) the flow path 222 and the accommodation space 212 of the tank body 210. For example, the first discharge port 224 may be the opening at the bottom of the inlet pipe 220.

The second discharge port 226 may be opened at a sidewall 221 of the inlet pipe 220, and may communicate with the flow path 222 and the accommodation space 212 of the tank body 210. For example, the second discharge port 226 may be an opening in the sidewall 221 of the inlet pipe 220.

At least a portion of the second discharge port 226 may be located on a level, higher than the first discharge port 224 in the height direction H of the tank body 210.

The liquid storage apparatus 200 may be configured such that the processing liquid L flows into the accommodation space 212 of the tank body 210 through the inlet pipe 220, which includes the first discharge port 224 and the second discharge port 226. When the accommodation space 212 is empty or a level (e.g., a vertical level or a height) of the processing liquid L in the accommodation space 212 is lower than the level of the first discharge port 224 of the inlet pipe 220, the processing liquid L flowing in the flow path 222 of the inlet pipe 220 may flow into the accommodation space 212 through the first discharge port 224 and the second discharge port 226. When the level of the processing liquid L in the accommodation space 212 is higher than or equal to the level of the first discharge port 224 of the inlet pipe 220, the processing liquid L flowing in the flow path 222 of the inlet pipe 220 may flow into the accommodation space 212 through only the second discharge port 226. Therefore, in a process of filling the accommodation space 212 of the liquid storage apparatus 200 with the processing liquid L at a certain level, the processing liquid L may flow through the second discharge port 226 of the inlet pipe 220 instead of the first discharge port 224 of the inlet pipe 220. Therefore, even when microbubbles B are generated during the process of filling the processing liquid L, the microbubbles B may quickly rise to a surface of the processing liquid L to efficiently remove the bubbles in the processing liquid L. The microbubbles B may more quickly rise to the surface because the level at which they enter the accommodation space 212 through the second discharge port 226 is higher than a level at which they would have entered the accommodation space 212 through the first discharge port 224.

In example embodiments, the liquid storage apparatus 200 may be configured such that the filling of the processing liquid L starts through the inlet pipe 220 when the level of the processing liquid L in the accommodation space 212 of the tank body 210 is located at a first set level L1 (see, e.g., FIG. 3). The first set level L1 may be located at a level, higher than the level of the first discharge port 224. The first set level L1 may be located to be closer to an upper surface of the accommodation space 212 than to the lower surface of the accommodation space 212. For example, a distance from the first set level L1 to the lower surface of the accommodation space 212 in the height direction H of the tank body 210 may be greater than a distance from the first set level L1 to the upper surface of the accommodation space 212. In example embodiments, the liquid storage apparatus 200 may be configured such that after the filling of the processing liquid L starts at the first set level L1, the filling of the processing liquid L may be performed until the level of the processing liquid L in the accommodation space 212 of the tank body 210 reaches a second set level L2. In the height direction H of the tank body 210, the second set level L2 may be higher than the first set level L1, and may be located at a level between the first set level L1 and the upper surface of the accommodation space 212. The second set level L2 may be adjacent to the upper surface of the accommodation space 212. A distance between the first set level L1 and the second set level L2 may be smaller than a distance between the first set level L1 and the outlet portion 230. Therefore, when the processing liquid L flows into the accommodation space 212 of the tank body 210, the processing liquid L may not flow in through the first discharge port 224 located on a lower end of the inlet pipe 220, but may flow in through the second discharge port 226 located on a sidewall of the inlet pipe 220, such that distribution of the generated microbubbles B may remain in an upper portion of the processing liquid L. Therefore, a physical separation distance between the microbubble B and the outlet 230 connected to the lower surface of the accommodation space 212 may be maintained to be relatively large. Thus, when the processing liquid L is discharged through the outlet 230, and is supplied to the substrate W, the microbubble B may be effectively prevented from being incorporated into the substrate W.

In example embodiments, the liquid storage apparatus 200 may further include a first level sensor S1 disposed in or on the tank body 210 and sensing the presence of the processing liquid L at the first set level L1 of the processing liquid L, and a second level sensor S2 sensing the presence of the processing liquid L at the second set level L2 at which the filling of the processing liquid L in the accommodation space 212 is completed. When the first level sensor S1 senses that a level of the processing liquid L in the accommodation space 212 of the tank body 210 is located at the first set level L1, filling of the processing liquid L into the accommodation space 212 through the inlet pipe 220 may begin. During the process of filling the processing liquid L, when the second level sensor S2 senses that a level of the processing liquid L in the accommodation space 212 of the tank body 210 may be located at the second set level L2, filling of the processing liquid L into the accommodation space 212 may be terminated. According to this configuration, filling of the processing liquid L through the inlet pipe 220 may be performed until the processing liquid L in the accommodation space 212 of the tank body 210 reaches the second set level L2 from the first set level L1.

The second discharge port 226 of the inlet pipe 220 may be implemented in various forms. The second discharge port 226 may include a single discharge port or may include one or more second discharge sub-ports on the sidewall 221 of the inlet pipe 220. In example embodiments, as illustrated in FIGS. 2 and 3, a single second discharge port 226 may be disposed on the sidewall 221 of the inlet pipe 220, and may have a slit shape extending in an extension direction of the inlet pipe 220. In example embodiments, the inlet pipe 220 may have a cylindrical shape, but is not limited thereto, and may be formed in various shapes such as an elliptical shape, a polygonal shape, or the like. The second discharge port 226 may be formed to extend vertically on the sidewall 221 of the inlet pipe 220 in the extension direction of the inlet pipe 220. The second discharge port 226 may be easily formed by cutting a portion of the sidewall 221 of the inlet pipe 220, but is not limited thereto, and an inlet pipe 220 provided with the second discharge port 226 may be manufactured separately. When viewed in a cross-section of the inlet pipe 220, the second discharge port 226 may be formed over a half region of the sidewall 221 in a circumferential direction of the inlet pipe 220 or over a region smaller than the half region. For example, when viewed in a cross-sectional view along the height direction, the second discharge port 226 may be formed to extend less than or equal to halfway around a circumference of the inlet pipe 220. When viewed in the cross-section of the inlet pipe 220, a maximum width D of the second discharge port 226 may be located in a range of 0.25 to 1 of a diameter DI of the inlet pipe 220. For example, a maximum width of the second discharge port 226 in a horizontal direction perpendicular to the height direction may be in a range of 0.25 times the diameter DI of the inlet pipe 220 to the diameter DI of the inlet pipe. For example, the second discharge port 226 may be formed in a slit shape extending vertically in the extension direction of the inlet pipe 220 on the sidewall 221 of the inlet pipe 220, and may have the same or different widths of the second discharge port 226 in the extension direction of the inlet pipe 220. For example, the width of the second discharge port 226 in the horizontal direction may be uniform or may vary along the length of the second discharge port 226 in the height direction.

In example embodiments, as illustrated in FIG. 3, the second discharge port 226 may be formed in a slit shape extending vertically in the extension direction of the inlet pipe 220 on the sidewall 221 of the inlet pipe 220, and may have the same widths of the second discharge port 226 in the extension direction of the inlet pipe 220. For example, the width of the second discharge port 226 in the horizontal direction may be uniform along the length of the second discharge port 226 in the height direction When viewed in the cross-section of the inlet pipe 220, the maximum width D of the second discharge port 226 may be in a range of 0.25 to 0.8 of the diameter of the inlet pipe 220, and as an example, as illustrated in FIG. 3, when viewed in the cross-section of the inlet pipe 220, the second discharge port 226 may be formed over a region smaller than the half region of the sidewall 221 in the circumferential direction of the inlet pipe 220, and the maximum width D of the second discharge port 226 may be approximately 0.35 of the diameter DI of the inlet pipe 220, but is not limited thereto.

When the processing liquid L flows into the accommodation space 212 of the tank body 210 through the inlet pipe 220 in which the second discharge port 226 is disposed, the processing liquid L may spread out on a surface of the processing liquid L remaining in the accommodation space 212, such that the microbubbles B remain in the upper portion of the processing liquid L and quickly rise to the surface of the processing liquid L, thereby enabling efficient removal of the microbubbles B.

In the height direction H of the tank body 210, a portion of the second discharge port 226 may be located at a level, lower than or equal to the first set level L1, and a different portion of the second discharge port 226 may be located at a level, higher than or equal to the second set level L2. In the height direction H of the tank body 210, a first end 226a of the second discharge port 226 may be located at a level, higher than the first set level L1. For example, in the height direction H of the tank body 210, the second discharge port 226 may have an extension length extending across (e.g., spanning) the first set level L1 and the second set level L2. Therefore, since the entirety of the filling of the processing liquid L into the accommodation space 212 of the tank body 210 at a level between the first set level L1 and the second set level L2 may be performed through the second discharge port 226 of the inlet pipe 220, most of the bubbles generated by discharging the processing liquid L remaining in the accommodation space 212 through the second discharge port 226 may be distributed in the upper portion of the processing liquid L. Therefore, the bubbles generated during the process of filling the processing liquid L may quickly rise to the surface of the processing liquid L, and may be efficiently removed, to effectively prevent such bubbles from remaining in the processing liquid L and incorporating into the substrate W through the outlet portion 230 connected to the lower surface of the accommodation space 212 to cause occurrence of defects. In addition, during the process of filling the processing liquid L, the second discharge port 226 for discharging the processing liquid L may not be blocked by the processing liquid L remaining in the accommodation space 212, such that pressure resistance when discharging the processing liquid L is reduced, such that the filling of the processing liquid L may be performed smoothly and quickly.

In example embodiments, the first end 226a of the second discharge port 226 may be located to be adjacent to a connection part 220a of the inlet pipe 220 connected to the upper surface of the accommodation space 212, and a second end 226b of the second discharge port 226, opposite to the first end 226a, may be located to be adjacent to the first discharge port 224. In the height direction H of the tank body 210, the first end 226a of the second discharge port 226 may be adjacent to the upper surface of the accommodation space 212, and may be higher than the first set level L1. The first end 226a of the second discharge port 226 may be spaced apart from the connection part 220a of the inlet pipe 220 by a first separation distance D1. The first separation distance D1 may be 0 mm<D1≤5 mm, but is not limited thereto, and may be appropriately set according to actual needs. In the height direction H of the tank body 210, the second end 226b of the second discharge port 226 may be located at a level, lower than the first set level L1 and higher than the level of the first discharge port 224, and may be adjacent to the first discharge port 224. The second end 226b of the second discharge port 226 may be spaced apart from the first discharge port 224 by a second separation distance D2. The second separation distance D2 may be 0 mm<D2≤5 mm, but is not limited thereto, and may be appropriately set according to actual needs. Since the two ends of the second discharge port 226 may have a structure spaced apart from the connection part 220a and the lower end of the inlet pipe 220, to easily process the second discharge port 226 for the inlet pipe 220 and to secure durability of the inlet pipe 220, such that the inlet pipe 220 may be prevented from being torn or damaged during use. However, arrangement of the second discharge port 226 on the sidewall 221 of the second inlet pipe 220 in the present inventive concept is not limited thereto, and may be implemented in various forms.

The second end 226b of the second discharge port 226 may be located at a level, higher than a third set level L3 in the height direction H of the tank body 210. The third set level L3 may be a level, higher than the lower surface of the accommodation space 212 and lower than the first set level L1. The third set level L3 may be disposed to be adjacent to the lower surface of the accommodation space 212. The first discharge port 224 formed on a lower end of the inlet pipe 220 may be disposed at a level, lower than the third set level L3. The second discharge port 226 of the inlet pipe 220 may extend to a position close to the third set level L3. For example, the second end 226b of the second discharge port 226 may be adjacent to the third set level L3 in the height direction H of the tank body 210.

In example embodiments, when the level of the processing liquid L in the accommodation space 212 of the tank body 210 is located at the third set level L3, an entire operation of the liquid supply system may be stopped. The liquid storage apparatus 200 may further include a third level sensor S3 sensing that the level of the processing liquid L is at the third set level L3. When the third level sensor S3 senses that the level of the processing liquid L in the accommodation space 212 of the tank body 210 is at the third set level L3, the liquid supply system may be configured to stop the entire operation including an operation of the liquid storage apparatus 200.

In example embodiments, the inlet pipe 220 may be spaced apart from a central portion (e.g., a radial center) of the accommodation space 212 in the accommodation space 212 of the tank body 210. The inlet pipe 220 may extend vertically between the central portion of the accommodation space 212 and an inner sidewall of the tank body 210 in the accommodation space 212, and may be disposed to be biased to one side, based on the central portion of the accommodation space 212. The inlet pipe 220 may be disposed to be adjacent to the inner sidewall of the tank body 210 in the accommodation space 212. The second discharge port 226 may be disposed to face the central portion (e.g., the radial center) of the accommodation space 212. Therefore, the processing liquid L discharged through the second discharge port 226 of the inlet pipe 220 may be filled from the center region of the accommodation space 212.

In example embodiments, the lower end of the inlet pipe 220 may be disposed to be adjacent to the lower surface of the accommodation space 212 in the accommodation space 212. For example, the first discharge port 224 formed on the lower end of the inlet pipe 220 may be disposed to be adjacent to the lower surface of the accommodation space 212. Furthermore, to smoothly flow the processing liquid L into the accommodation space 212 through the first discharge port 224, the first discharge port 224 formed on the lower end of the inlet pipe 220 may be adjacent to and spaced apart from the lower surface of the accommodation space 212.

According to the liquid storage apparatus 200 having such a configuration and the liquid supply system including the same, bubbles (including microbubbles B) included in the processing liquid L in the liquid storage apparatus 200 may quickly rise to the surface of the processing liquid L, such that the bubbles in the processing liquid L may be efficiently removed.

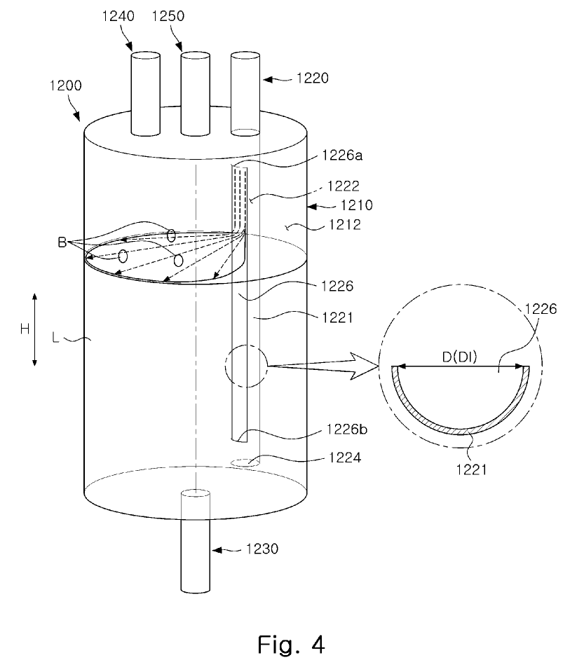

FIG. 4 is a view illustrating an inlet portion having a different shape in a liquid storage apparatus according to example embodiments.

Referring to FIG. 4, a liquid storage apparatus 1200 may include a tank body 1210, an inlet pipe 1220, and an outlet portion 1230. The liquid storage apparatus 1200 may further include a gas supply portion 1240. The gas supply portion 1240 may be disposed on the tank body 1210 of the liquid storage apparatus 1200, and may supply a pressurized gas to an accommodation space 1212 of the tank body 1210.

The liquid storage apparatus 1200 may further include a discharge portion 1250.

In the liquid storage apparatus 1200, the tank body 1210, the outlet portion 1230, the gas supply portion 1240, and the discharge portion 1250 may be the same as the tank body 210, the outlet portion 230, the gas supply portion 240, and the discharge portion 250, described above, and a description thereof will be omitted to avoid redundancy. However, the present inventive concept is not limited thereto, and, as necessary, the tank body 1210, the outlet portion 1230, the gas supply portion 1240, and the discharge portion 1250 may have a different structure from the tank body 210, the outlet portion 230, the gas supply portion 240, and the discharge portion 250, described above.

The inlet pipe 1220 may be disposed to extend in a height direction H of the tank body 1210 in the accommodation space 1212 of the tank body 1210. The inlet pipe 1220 may be disposed on and in the tank body 1210, and a portion of the inlet pipe 1220 may be exposed from an upper portion of the tank body 1210, and a different portion of the inlet pipe 1220 may be disposed in the accommodation space 1212 of the tank body 1210.

The inlet pipe 1220 may include a flow path 1222 through which a processing liquid L flows, a first discharge port 1224, and a second discharge port 1226.

The flow path 1222 may be formed to extend in the height direction H in the inlet pipe 1220. The first discharge port 1224 may be opened on a lower end of the inlet pipe 1220, and may communicate with the flow path 1222 and the accommodation space 1212 of the tank body 1210. For example, the first discharge port 1224 may be the opening at the bottom of the inlet pipe 1220. The flow path 1222 and the first discharge port 1224 of the inlet pipe 1220 may be the same as the flow path 222 and the first discharge port 224 of the inlet pipe 220, described above, and a description thereof will be omitted to avoid redundancy.

The second discharge port 1226 may be opened on a sidewall 1221 of the inlet pipe 1220, and may communicate with the flow path 1222 and the accommodation space 1212 of the tank body 1210. For example, the second discharge port 1226 may be an opening in the sidewall 1221 of the inlet pipe 1220. The second discharge port 1226 of the inlet pipe 1220 may be implemented in various forms. A single second discharge port 1226 may be disposed on the sidewall 1221 of the inlet pipe 1220, and may have a slit shape extending in an extension direction of the inlet pipe 1220. The second discharge port 1226 may include a first end 1226a located on an upper side, and a second end 1226b located on a lower side, in the height direction H of the tank body 1210.

The second discharge port 1226 may be located at a higher level than the level of the first discharge port 1224 in the height direction H of the tank body 1210. The second end 1226b of the second discharge port 1226 may be located at a higher level than the level of the first discharge port 1224. When viewed in a cross-section of the inlet pipe 1220, the second discharge port 1226 may be formed over a half region of the sidewall 1221 in a circumferential direction of the inlet pipe 1220 or over a region smaller than the half region. When viewed in the cross-section of the inlet pipe 1220, a maximum width D of the second discharge port 1226 may be in a range of 0.25 to 1 of a diameter DI of the inlet pipe 1220. In example embodiments, when viewed in the cross-section of the inlet pipe 1220, the maximum width D of the second discharge port 1226 may be in a range of 0.8 to 1 of the diameter DI of the inlet pipe 1220. As illustrated in FIG. 4, when viewed in the cross-section of the inlet pipe 1220, the second discharge port 1226 may be formed over a half region of the sidewall 1221 in the circumferential direction of the inlet pipe 1220, and when viewed in the cross-section of the inlet pipe 1220, the maximum width D of the second discharge port 1226 may be approximately equal to the diameter DI of the inlet pipe 1220.

According to such a configuration, rapid charging of the processing liquid L into the accommodation space 1212 of the liquid storage tank 1200 may be realized, and during a process of filling the processing liquid L, bubbles included in the processing liquid L in the liquid storage apparatus 1200 may quickly rise to a surface of the processing liquid L, such that bubbles in the processing liquid L may be efficiently removed.

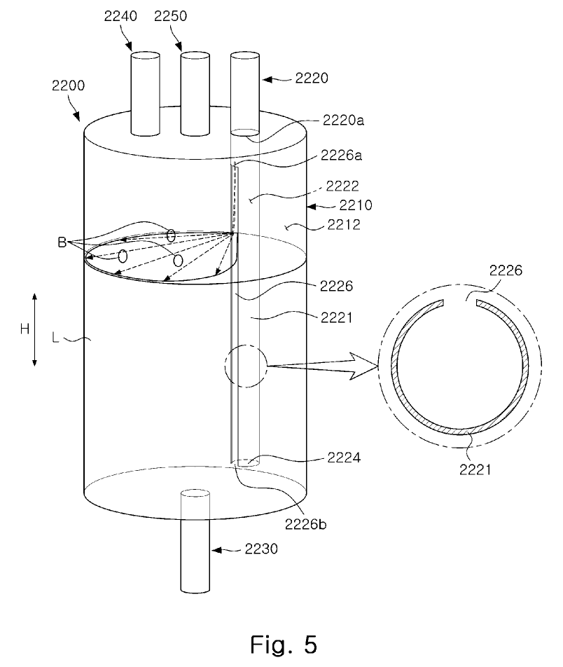

FIG. 5 is a view illustrating a liquid storage apparatus according to example embodiments.

Referring to FIG. 5, a liquid storage apparatus 2200 may include a tank body 2210, an inlet pipe 2220, and an outlet portion 2230. The liquid storage apparatus 2200 may further include a gas supply portion 2240. The gas supply portion 2240 may be disposed on the tank body 2210 of the liquid storage apparatus 2200, and may be connected to a pressurized gas supply line 2300 to supply a pressurized gas to an accommodation space 2212 of the tank body 2210. The liquid storage apparatus 2200 may further include a discharge portion 2250.

In the liquid storage apparatus 2200, the tank body 2210, the outlet portion 2230, the gas supply portion 2240, and the discharge portion 2250 may be the same as the tank body 210, the outlet portion 230, the gas supply portion 240, and the discharge portion 250, described above, and a description thereof will be omitted to avoid redundancy. However, the present inventive concept is not limited thereto, and, as necessary, the tank body 2210, the outlet portion 2230, the gas supply portion 2240, and the discharge portion 2250 may have a different structure from the tank body 210, the outlet portion 230, the gas supply portion 240, and the discharge portion 250, described above.

The inlet pipe 2220 may be disposed to extend in a height direction H of the tank body 2210 in the accommodation space 2212 of the tank body 2210. The inlet pipe 2220 may be disposed in and on the tank body 2210, and a portion of the inlet pipe 2220 may be exposed from an upper portion of the tank body 2210, and a different portion of the inlet pipe 2220 may be disposed in the accommodation space 2212 of the tank body 2210.

The inlet pipe 2220 may include a flow path 2222 through which a processing liquid L flows, a first discharge port 2224, and a second discharge port 2226.

The flow path 2222 may be formed to extend in the height direction H in the inlet pipe 2220. The first discharge port 2224 may be opened on a lower end of the inlet pipe 2220, and may communicate with the flow path 2222 and the accommodation space 2212 of the tank body 2210. For example, the first discharge port 2224 may be the opening at the bottom of the inlet pipe 2220. The flow path 2222 and the first discharge port 2224 of the inlet pipe 2220 may be the same as the flow path 222 and the first discharge port 224 of the inlet pipe 220, described above, and a description thereof will be omitted to avoid redundancy.

The second discharge port 2226 may be opened on a sidewall 2221 of the inlet pipe 2220, and may communicate with the flow path 2222 and the accommodation space 2212 of the tank body 2210. For example, the second discharge port 2226 may be an opening in the sidewall 2221 of the inlet pipe 2220.

The second discharge port 2226 may be implemented in various forms. A single second discharge port 2226 may be disposed on the sidewall 2221 of the inlet pipe 2220, and may have a slit shape extending in an extension direction of the inlet pipe 2220. The second discharge port 2226 may include a first end 2226a located on an upper side, and a second end 2226b located on a lower side, in the height direction H of the tank body 2210.

In the height direction H of the tank body 2210, a portion of the second discharge port 2226 may be located at a higher level than the level of the first discharge port 2224 and a different portion of the second discharge port 2226 may be located at the same level as the level of the first discharge port 2224. In example embodiments, as illustrated in FIG. 5, the second end 2226b of the second discharge port 2226 may be opened at a lower end of the inlet pipe 2220, and may be connected to the first discharge port 2224 of the inlet pipe 2220. All other portions except the second end 2226b of the second discharge port 2226 may be located at a higher level than the first discharge port 2224. For example, the first discharge port 2224 and the second discharge port may be continuous with each other with no material of the inlet pipe 2220 or other barrier formed between them. In addition, as illustrated in FIG. 5, the first end 2226a of the second discharge port 2226 is illustrated as being disposed to be adjacent to and spaced apart from a connection part 2220a of the inlet pipe 2220 connected to an upper surface of the accommodation space 2212, but is not limited thereto, and the first end 2226a of the second discharge port 2226 may be in contact with the connection part 2220a of the inlet pipe 2220.

In the embodiments, the second discharge port (226, 1226, and 2226) is illustrated as being a single discharge port on the sidewall (221, 1221, and 2221) of the inlet pipe (220, 1220, and 2220), but is not limited thereto, and the second discharge port may be disposed in plural (e.g., as second discharge sub-ports) on the sidewall of the inlet pipe, which will be specifically described through embodiments below.

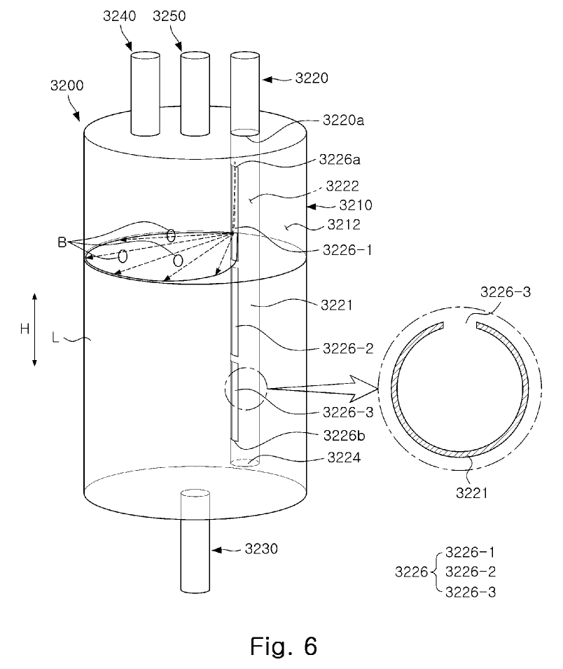

FIG. 6 is a view illustrating a liquid storage apparatus according to example embodiments.

Referring to FIG. 6, a liquid storage apparatus 3200 may include a tank body 3210, an inlet pipe 3220, and an outlet portion 3230. The liquid storage apparatus 3200 may further include a gas supply portion 3240. The gas supply portion 3240 may be disposed on the tank body 3210 of the liquid storage apparatus 3200, and may be connected to a pressurized gas supply line 3300 to supply a pressurized gas to an accommodation space 3212 of the tank body 3210. The liquid storage apparatus 3200 may further include a discharge portion 3250.

In the liquid storage apparatus 3200, the tank body 3210, the outlet portion 3230, the gas supply portion 3240, and the discharge portion 3250 may be the same as the tank body 210, the outlet portion 230, the gas supply portion 240, and the discharge portion 250, described above, and a description thereof will be omitted to avoid redundancy. However, the present inventive concept is not limited thereto, and, as necessary, the tank body 3210, the outlet portion 3230, the gas supply portion 3240, and the discharge portion 3250 may have a different structure from the tank body 210, the outlet portion 230, the gas supply portion 240, and the discharge portion 250, described above.

The inlet pipe 3220 may be disposed to extend in a height direction H of the tank body 3210 in the accommodation space 3212 of the tank body 3210. The inlet pipe 3220 may be disposed in and on the tank body 3210, and a portion of the inlet pipe 3220 may be exposed from an upper portion of the tank body 3210, and a different portion of the inlet pipe 3220 may be disposed in the accommodation space 3212 of the tank body 3210.

The inlet pipe 3220 may include a flow path 3222 through which a processing liquid L flows, a first discharge port 3224, and a second discharge port 3226.

The flow path 3222 may be formed to extend in the height direction H in the inlet pipe 3220. The first discharge port 3224 may be opened on a lower end of the inlet pipe 3220, and may communicate with the flow path 3222 and the accommodation space 3212 of the tank body 3210. For example, the first discharge port 3224 may be the opening at the bottom of the inlet pipe 3220. The flow path 3222 and the first discharge port 3224 of the inlet pipe 3220 may be the same as the flow path 222 and the first discharge port 224 of the inlet pipe 220, described above, and a description thereof will be omitted to avoid redundancy.

The second discharge port 3226 may be opened on a sidewall 3221 of the inlet pipe 3220, and may communicate with the flow path 3222 and the accommodation space 3212 of the tank body 3210. For example, the second discharge port 3226 may be an opening in the sidewall 3221 of the inlet pipe 3220. The second discharge port 3226 of the inlet pipe 3220 may be implemented in various forms. The second discharge port 3226 may be disposed in plural on the sidewall 3221 of the inlet pipe 3220, and may have a slit shape extending in an extension direction of the inlet pipe 3220. The second discharge port 3226 may be disposed as a plurality of discharge sub-ports 3226 spaced apart from each other on the sidewall 3221 in the extension direction of the inlet pipe 3220. In example embodiments, as illustrated in FIG. 6, the second discharge port 3226 may include a first discharge sub-port 3226-1, a second discharge sub-port 3226-2, and a third discharge sub-port 3226-3, sequentially disposed spaced apart from each other from top to bottom, in the extension direction of the inlet pipe 3220 on the sidewall 3221 of the inlet pipe 3220. The first discharge sub-port 3226-1, the second discharge sub-port 3226-2, and the third discharge sub-port 3226-3 may have the same shape and size as each other, as illustrated in FIG. 6, but is not limited thereto, and may be formed in different shapes or sizes from each other.

The second discharge port 3226 may include a first end 3226a located on an upper side, and a second end 3226b located on a lower side, in the height direction H of the tank body 3210. The first discharge sub-port 3226-1, the second discharge sub-port 3226-2, and the third discharge sub-port 3226-3 may be arranged vertically in the extension direction of the inlet pipe 3220 on the sidewall 3221 of the inlet pipe 3220. The first end 3226a of the first discharge sub-port 3226-1 located on an uppermost side in the height direction H of the tank body 3210 may be located at a level, lower than an upper end of the accommodation space 3212 of the tank body 3210, and the second end 3226b of the third discharge sub-port 3226-3 located on a lowermost side in the height direction H of the tank body 3210 may be located at a level, higher than the level of the first discharge port 3224.

In example embodiments, the first end 3226a of the first discharge sub-port 3226-1 may be located to be adjacent to and spaced apart from a connection part 3220a of the inlet pipe 3220 connected to an upper surface of the accommodation space 3212. The second end 3226b of the third discharge sub-port 3226-3 may be located to be adjacent to and spaced from the first discharge port 3224. Therefore, in the second discharge port 3226 including the first discharge sub-port 3226-1, the second discharge sub-port 3226-2, and the third discharge sub-port 3226-3, the first end 3226a of the first discharge sub-port 3226-1 and the second end 3226b of the third discharge sub-port 3226-3 may have a structure spaced from the connection part 3220a of the inlet pipe 3220 and the first discharge port 3224, respectively, thereby securing durability of the inlet pipe 3220 and preventing the inlet pipe 3220 from being torn or damaged during use. However, arrangement of the second discharge port 3226 on the sidewall 3221 of the inlet pipe 3220 in the present inventive concept is not limited thereto, and in other embodiments, the first end 3226a of the first discharge sub-port 3226-1 may be in contact with the connection part 3220a of the inlet pipe 3220, and/or the second end 3226b of the third discharge sub-port 3226-3 may be connected to the first discharge port 3224 of the inlet pipe 3220.

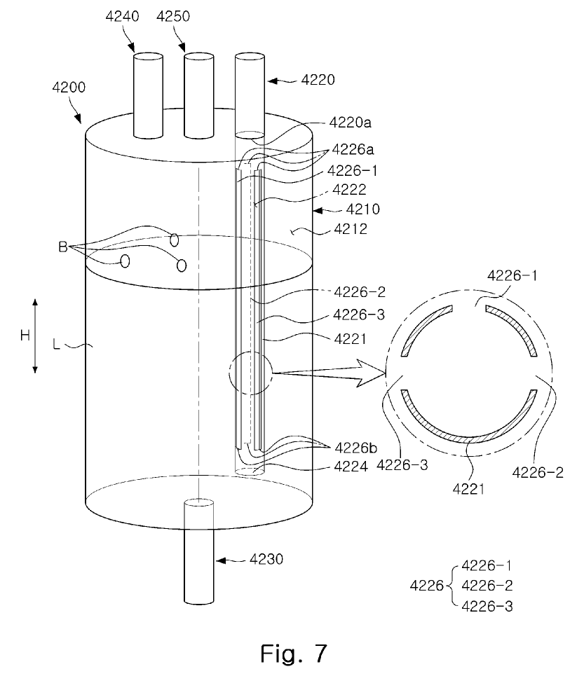

FIG. 7 is a view illustrating a liquid storage apparatus according to example embodiments.

Referring to FIG. 7, a liquid storage apparatus 4200 may include a tank body 4210, an inlet pipe 4220, and an outlet portion 4230. The liquid storage apparatus 4200 may further include a gas supply portion 4240. The gas supply portion 4240 may be disposed on the tank body 4210 of the liquid storage apparatus 4200, and may be connected to a pressurized gas supply line 4300 to supply a pressurized gas to an accommodation space 4212 of the tank body 4210. The liquid storage apparatus 4200 may further include a discharge portion 4250.

In the liquid storage apparatus 4200, the tank body 4210, the outlet portion 4230, the gas supply portion 4240, and the discharge portion 4250 may be the same as the tank body 210, the outlet portion 230, the gas supply portion 240, and the discharge portion 250, described above, and a description thereof will be omitted to avoid redundancy. However, the present inventive concept is not limited thereto, and, as necessary, the tank body 4210, the outlet portion 4230, the gas supply portion 4240, and the discharge portion 4250 may have a different structure from the tank body 210, the outlet portion 230, the gas supply portion 240, and the discharge portion 250, described above.

The inlet pipe 4220 may be disposed to extend in a height direction H of the tank body 4210 in the accommodation space 4212 of the tank body 4210. The inlet pipe 4220 may be disposed in and on the tank body 4210, and a portion of the inlet pipe 4220 may be exposed from an upper portion of the tank body 4210, and a different portion of the inlet pipe 4220 may be disposed in the accommodation space 4212 of the tank body 4210.

The inlet pipe 4220 may include a flow path 4222 through which a processing liquid L flows, a first discharge port 4224, and a second discharge port 4226.

The flow path 4222 may be formed to extend in the height direction H in the inlet pipe 4220. The first discharge port 4224 may be opened on a lower end of the inlet pipe 4220, and may communicate with the flow path 4222 and the accommodation space 4212 of the tank body 4210. For example, the first discharge port 4224 may be the opening at the bottom of the inlet pipe 4220. The flow path 4222 and the first discharge port 4224 of the inlet pipe 4220 may be the same as the flow path 222 and the first discharge port 224 of the inlet pipe 220, described above, and a description thereof will be omitted to avoid redundancy.

The second discharge port 4226 may be opened on a sidewall 4221 of the inlet pipe 4220, and may communicate with the flow path 4222 and the accommodation space 4212 of the tank body 4210. For example, the second discharge port 4226 may be an opening in the sidewall 4221 of the inlet pipe 4220. The second discharge port 4226 of the inlet pipe 4220 may be implemented in various forms. The second discharge ports 4226 may be disposed in plural on the sidewall 4221 of the inlet pipe 4220, and may each have a slit shape extending in an extension direction of the inlet pipe 4220. The second discharge port 4226 may be disposed as a plurality of discharge sub-ports 4226 spaced apart from each other in a circumferential direction of the inlet pipe 4220 on the sidewall 4221 of the inlet pipe 4220, and each of the discharge sub-ports 4226 may have a slit shape extending in the extension direction of the inlet pipe 4220. In example embodiments, as illustrated in FIG. 7, the second discharge port 4226 may include a first discharge sub-port 4226-1, a second discharge sub-port 4226-2, and a third discharge sub-port 4226-3, spaced apart from each other in the circumferential direction of the inlet pipe 4220 on the sidewall 4221 of the inlet pipe 4220. Intervals between the first discharge sub-port 4226-1, the second discharge sub-port 4226-2, and the third discharge sub-port 4226-3 in the circumferential direction of the inlet pipe 4220 may be the same as or different from each other. In an example embodiment, at least one of the first discharge sub-port 4226-1, the second discharge sub-port 4226-2, and the third discharge sub-port 4226-3 may be disposed on a sidewall portion facing a central portion (e.g., an axial center) of the accommodation space on the sidewall 4221 of the inlet pipe 4220 as illustrated in FIG. 7, and may have the same shape and size as each other, but is not limited thereto, and may be spaced apart from each other at the same interval or may have different shapes or sizes from each other. Each of the first discharge sub-port 4226-1, the second discharge sub-port 4226-2, and the third discharge port 4226-3 may have a slit shape extending in the extension direction of the inlet pipe 4220.

Each of the first discharge sub-port 4226-1, the second discharge sub-port 4226-2, and the third discharge sub-port 4226-3 may include a first end 4226a located on an upper side, and a second end 4226b located on a lower side, in the height direction H of the tank body 4210.

The first end 4226a of each of the first discharge sub-port 4226-1, the second discharge sub-port 4226-2, and the third discharge sub-port 4226-3 may be located at a level, lower than an upper end of the accommodation space 4212 of the tank body 4210, and the second end 4226b of each of the first discharge sub-port 4226-1, the second discharge sub-port 4226-2, and the third discharge sub-port 4226-3 may be located at a level, higher than the first discharge port 4224.

In example embodiments, the first end 4226a of each of the first discharge sub-port 4226-1, the second discharge sub-port 4226-2, and the third discharge sub-port 4226-3 may be located to be adjacent to and spaced apart from a connection part 4220a of the inlet pipe 4220 connected to an upper surface of the accommodation space 4212. The second end 4226b of each of the first discharge sub-port 4226-1, the second discharge sub-port 4226-2, and the third discharge sub-port 4226-3 may be located to be adjacent to and spaced apart from the first discharge port 4224. Therefore, the second discharge port 4226 including the first discharge sub-port 4226-1, the second discharge sub-port 4226-2, and the third discharge sub-port 4226-3 may be applied to realize rapid filling of the processing liquid L into the accommodation space 4212 of the liquid storage tank 4200, and during a process of filling the processing liquid L, bubbles included in the processing liquid L in the liquid storage apparatus 4200 may quickly rise to a surface of the processing liquid L, to efficiently remove the bubbles in the processing liquid L.

Arrangement of the first discharge sub-port 4226-1, the second discharge sub-port 4226-2, and the third discharge sub-port 4226-3 on the sidewall 4221 of the inlet pipe 4220 is not limited thereto, and in other embodiments, the first end 4226a of each of the first discharge sub-port 4226-1, the second discharge sub-port 4226-2, and the third discharge sub-port 4226-3 may be in contact with the connection part 4220a of the inlet pipe 4220, and/or the second end 4226b of each of the first discharge sub-port 4226-1, the second discharge sub-port 4226-2, and the third discharge sub-port 4226-3 may be connected to the first discharge port 4224 of the inlet pipe 4220.

In addition, each of the first discharge sub-port 4226-1, the second discharge sub-port 4226-2, and the third discharge sub-port 4226-3 has been described as a single slit shape extending in the extension direction of the inlet pipe from the sidewall 4221 of the inlet pipe 4220, but is not limited thereto, and each of the first discharge sub-port 4226-1, the second discharge sub-port 4226-2, and the third discharge sub-port 4226-3 may be implemented as a plurality of slit shapes disposed spaced apart from each other in the extension direction of the inlet pipe 4220 from the sidewall 4221 of the inlet pipe 4220.

Aspects of the present inventive concept may provide a liquid storage apparatus and a liquid supply system, capable of efficiently removing bubbles from a processing liquid.

Aspects of the present inventive concept may provide a liquid storage apparatus and a liquid supply system, capable of efficiently removing bubbles from a processing liquid, since the processing liquid may flow into a liquid surface in a buffer tank to quickly rise the bubble included in the processing liquid.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A liquid storage apparatus comprising:
a tank body including an accommodation space configured to store a processing liquid;
an inlet pipe disposed on the tank body and in the accommodation space to flow the processing liquid into the accommodation space, the inlet pipe extending in a height direction of the tank body; and
an outlet pipe disposed on the tank body, the outlet pipe being configured such that the processing liquid flows out from the accommodation space through the outlet pipe,
wherein the inlet pipe includes:
a flow path configured such that the processing liquid flows through the flow path;
a first discharge port provided at a lower end of the inlet pipe and in communication with the flow path and the accommodation space; and
a second discharge port provided at a sidewall of the inlet pipe, wherein, in the height direction of the tank body, at least a portion of the second discharge port is located at a level that is higher than a level of the first discharge port, and wherein the second discharge port is in communication with the flow path and the accommodation space.

2. The liquid storage apparatus of claim 1, wherein, in the height direction of the tank body, a portion of the second discharge port is located at a level that is lower than or equal to a first set level of the processing liquid at which a filling process of the processing liquid into the accommodation space is configured to begin.

3. The liquid storage apparatus of claim 2, wherein, in the height direction of the tank body, a different portion of the second discharge port is located at a level that is higher than or equal to a second set level at which filling of the processing liquid is configured to be completed, and
wherein the second set level is adjacent to an upper surface of the accommodation space and is higher than the first set level.

4. The liquid storage apparatus of claim 1, wherein the second discharge port has a slit shape extending in an extension direction of the inlet pipe.

5. The liquid storage apparatus of claim 4, wherein the inlet pipe has a cylindrical shape, and when viewed in a cross-sectional view along the height direction, the second discharge port is formed to extend less than or equal to halfway around a circumference of the inlet pipe, and
wherein a maximum width of the second discharge port in a horizontal direction perpendicular to the height direction is in a range of 0.25 times a diameter of the inlet pipe to the diameter of the inlet pipe.

6. The liquid storage apparatus of claim 4, wherein a first end of the second discharge port in the height direction is located to be adjacent to a connection part of the inlet pipe connected to an upper surface of the accommodation space, and
wherein a second end of the second discharge port, which is opposite to the first end in the height direction, is located to be adjacent to the first discharge port.

7. The liquid storage apparatus of claim 6, wherein the first end of the second discharge port is spaced apart from the connection part of the inlet pipe by a first separation distance in the height direction.

8. The liquid storage apparatus of claim 6, wherein the second end of the second discharge port is spaced apart from the first discharge port by a second separation distance in the height direction.

9. The liquid storage apparatus of claim 1, wherein the second discharge port includes a plurality of discharge sub-ports provided in the sidewall and spaced apart from each other in an extension direction of the inlet pipe.

10. The liquid storage apparatus of claim 1, wherein the second discharge port includes a plurality of discharge sub-ports provided in the sidewall and spaced apart from each other in a circumferential direction of the inlet pipe, and
wherein each of the plurality of discharge sub-ports has a slit shape extending in an extension direction of the inlet pipe.

11. The liquid storage apparatus of claim 10, wherein the inlet pipe is spaced apart from a radial center of the accommodation space in the accommodation space, and
wherein the plurality of discharge sub-ports are disposed to face the radial center of the accommodation space.

12. The liquid storage apparatus of claim 1, wherein the inlet pipe is spaced apart from a radial center of the accommodation space in the accommodation space, and
wherein the second discharge port is disposed to face the radial center of the accommodation space.

13. The liquid storage apparatus of claim 12, wherein the inlet pipe is disposed to be adjacent to an inner sidewall of the tank body in the accommodation space.

14. The liquid storage apparatus of claim 1, wherein the lower end of the inlet pipe is disposed to be adjacent to a lower surface of the accommodation space in the accommodation space.

15. The liquid storage apparatus of claim 1, wherein the outlet pipe is connected to a lower surface of the accommodation space.

16. The liquid storage apparatus of claim 1, further including a gas supply disposed on the tank body and configured to supply a pressurized gas to the accommodation space.

17. The liquid storage apparatus of claim 1, further including a discharge line disposed on the tank body and configured to discharge a pressurized gas in the accommodation space.

18. The liquid storage apparatus of claim 1, further including:
a first level sensor disposed on the tank body and configured to sense a first set level of the processing liquid in the accommodation space at which filling of the processing liquid in the accommodation space is configured to begin, and
a second level sensor disposed on the tank body and configured to sense a second set level of the processing liquid in the accommodation space at which filling of the processing liquid in the accommodation space is configured to be completed,
wherein a distance between the first set level and the second set level is smaller than a distance between the first set level and the outlet pipe.

19. A liquid storage apparatus comprising:
a tank body including an accommodation space configured to store a processing liquid;
an inlet pipe disposed on the tank body and in the accommodation space to flow the processing liquid into the accommodation space, the inlet pipe extending in a height direction of the tank body;
an outlet pipe disposed on the tank body, the outlet pipe being configured such that the processing liquid flows out from the accommodation space through the outlet pipe; and
a first level sensor disposed on the tank body and configured to sense a first set level of the processing liquid in the accommodation space at which filling of the processing liquid in the accommodation space is configured to begin,
wherein the inlet pipe includes:
a flow path configured such that the processing liquid flows through the flow path;
a first discharge port provided at a lower end of the inlet pipe and in communication with the flow path and the accommodation space; and
a second discharge port having a slit shape extending in an extension direction of the inlet pipe, the second discharge port opening toward a radial center of the accommodation space, and the second discharge port being in communication with the flow path and the accommodation space, and
wherein, in the height direction of the tank body, a first end of the second discharge port is at a level higher than a level of the first discharge port, and a second end of the second discharge port opposite to the first end is adjacent to the first discharge port.

20. A liquid supply system comprising:
a liquid supply line of which one end is connected to a liquid supply source configured to supply a processing liquid;
a liquid storage apparatus disposed on the liquid supply line and configured to temporarily store therein the processing liquid supplied from the liquid supply source;
a pressurized gas supply line connected to the liquid storage apparatus;
a drain line connected to the liquid storage apparatus;
a pump disposed on the liquid supply line and configured to pump the processing liquid; and
a discharge nozzle disposed at the other end of the liquid supply line and configured to discharge the processing liquid supplied from the liquid storage apparatus to a substrate treatment device,
wherein the liquid storage apparatus includes:
a tank body including an accommodation space configured to store the processing liquid;
an inlet pipe disposed on the tank body and in the accommodation space to flow the processing liquid into the accommodation space, the inlet pipe extending in a height direction of the tank body;
an outlet pipe disposed on the tank body, the outlet pipe being configured such that the processing liquid flows out from the accommodation space through the outlet pipe;
a gas supply disposed on the tank body, connected to the pressurized gas supply line, and configured to supply a pressurized gas to the accommodation space; and
a discharge line disposed on the tank body and connected to the drain line, and
wherein the inlet pipe includes:
a flow path configured such that the processing liquid flows through the flow path;
a first discharge port provided at a lower end of the inlet pipe and in communication with the flow path and the accommodation space; and
a second discharge port provided at a sidewall of the inlet pipe, wherein at least a portion of the second discharge port is located at a level in the height direction that is higher than a level of the first discharge port, and wherein the second discharge port is in communication with the flow path and the accommodation space.
